(19) United States
(12) Patent Application Publication
(10) Pub. No.: US 2026/0107824 A1
(43) Pub. Date: Apr. 16, 2026

(54) SEMICONDUCTOR PACKAGE

(71) Applicant: Samsung Electronics Co., Ltd., Suwon-si (KR)

(72) Inventors: Yi Koan HONG, Suwon-si (KR); Jae-Wha PARK, Suwon-si (KR)

(21) Appl. No.: 19/352,536

(22) Filed: Oct. 8, 2025

(30) Foreign Application Priority Data
Oct. 14, 2024 (KR) 10-2024-0139485

(51) Int. Cl. H01L 23/31; H01L 23/00; H01L 23/29; H01L 25/065

(52) U.S. Cl. CPC H10W 74/121; H10W 90/00; H10W 74/47; H10W 90/26; H10W 90/297; H10W 90/792

(57) ABSTRACT

Provided is a semiconductor package, including a first chip, a second chip disposed on the first chip along a first direction, a first spacer film disposed below the second chip and covering at least a portion of a side surface of the first chip, and a first molding film disposed below the second chip and disposed to cover a side surface of the first spacer film, wherein the first spacer film and the first molding film include materials different from each other, and the side surface of the first spacer film is curved to be convex.

### CROSS-REFERENCE TO RELATED APPLICATIONS

This application claims the benefit of Korean Patent Application No. 10-2024-0139485, filed on Oct. 14, 2024, in the Korean Intellectual Property Office, the disclosure of which is incorporated herein by reference in its entirety.

### BACKGROUND

### 1. Field of the Invention

The present disclosure relates to a semiconductor package.

### 2. Description of the Related Art

A demand for highly functional, high-speed, and smaller electronic components has been increasing due to developments in the electronics industry. In response to this growing demand, a method of laminating and mounting several semiconductor chips on one package interconnection structure or laminating one package onto another package may be used. As an example, a high bandwidth memory (HBM) which can provide a high bandwidth by laminating multiple semiconductor chips on the same area of the substrate has been introduced. However, a semiconductor chip may be damaged during a process of grinding semiconductor chip surfaces and bonding the semiconductor chips to laminate several semiconductor chips.

### SUMMARY

An aspect provides a semiconductor package with improved reliability.

However, the goals to be achieved by example embodiments of the present disclosure are not limited to the objective described above and other objects may be clearly understood by those skilled in the art from the following example embodiments.

According to an aspect, there is provided a semiconductor package including a first chip, a second chip disposed on the first chip along a first direction, a first spacer film disposed below the second chip and covering at least a portion of a side surface of the first chip, and a first molding film disposed below the second chip and disposed to cover a side surface of the first spacer film, wherein the first spacer film and the first molding film include different materials and the side surface of the first spacer film is curved to be convex.

According to another aspect, there is also provided a semiconductor package including a first chip including a first front substrate and a first rear substrate disposed on the first front substrate along a first direction and penetrated by a first through via, a second chip disposed on the first chip along the first direction, a first blocking film disposed on an upper surface of the first front substrate, a first spacer film covering at least a portion of a side surface of the first chip below the second chip and not in contact with the first blocking film, a first molding film disposed to cover a side surface of the first spacer film below the second chip, a second spacer film disposed on the first chip and covering at least a portion of a side surface of the second chip, and a second molding film disposed on the first chip and disposed to cover a side surface of the second spacer film, wherein the first spacer film and the second spacer film include a first resin, and the first molding film and the second molding film include a second resin that is different from the first resin.

According to still another aspect, there is also provided a semiconductor package including a first chip including a first front substrate and a first rear substrate disposed on the first front substrate along a first direction and penetrated by a first through via, a second chip including a second rear substrate disposed on the first rear substrate and penetrated by a second through via and a second front substrate disposed on the second rear substrate, a first blocking film disposed on an upper surface of the first front substrate, a first spacer film disposed to cover a side surface of the first rear substrate on the first front substrate and not in contact the first blocking film, a first molding film disposed to cover a side surface of the first spacer film below the second chip, a second blocking film disposed on a lower surface of the second front substrate, a second spacer film disposed to cover a side surface of the second rear substrate below the second front substrate, not in contact with the second blocking film, and in contact with the first spacer film, and a second molding film disposed to cover a side surface of the second spacer on the first chip and in contact with the first molding film.

Additional aspects of example embodiments will be set forth in part in the description which follows and, in part, will be apparent from the description.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is an example drawing for describing a semiconductor package according to example embodiments;

FIG. 2 is an example drawing for describing a semiconductor package according to other example embodiments;

FIG. 3 is an example drawing for describing a semiconductor package according to still other example embodiments;

FIG. 4 is an example drawing for describing a semiconductor package according to still other example embodiments;

FIGS. 5 through 12 are example drawings showing an intermediate process for explaining a method of fabricating a semiconductor package according to example embodiments illustrated in FIG. 1; and

FIG. 13 is an example drawing showing an intermediate process for explaining a method of fabricating a semiconductor package according to other example embodiments illustrated in FIG. 2.

### DETAILED DESCRIPTION

It should be understood the embodiments described in the present disclosure and configurations illustrated in the accompanying drawings are merely examples and do not represent all of the technical spirit of the present invention, and it should be understood that various equivalents and modifications that may replace the disclosed embodiments within the scope of this invention.

In the following descriptions, descriptions regarding a singular element also apply to all such elements unless an apparently and contextually conflicting description is present. When a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

Ordinal numbers “first,” “second,” etc., may be used simply as labels to distinguish similar elements from one another. It should be appreciated that such labels may be vary with respect to a particular element such that a “first” element may be referred to elsewhere in the disclosure or claims as a “second” element, and similarly, a “second” element may be referred to as a “first” element. In addition, in the drawings, such as shapes and sizes of elements may be exaggerated for clarity.

In addition, it should be noted that directional expressions such as an upper side, an upper surface, a lower side, a lower surface, a side surface, a front surface, or a rear surface may be based on directions illustrated in the drawings for ease of description of direction, relationships, etc. It will thus be understood that these directional descriptions are not in relation to real world directions (and would still be relevant even when a direction of a corresponding device changes in the real world). In the drawings, shapes and sizes of elements may be exaggerated for clarity.

Hereinafter, example embodiments according to the technical spirit of the present disclosure will be described with reference to the drawings.

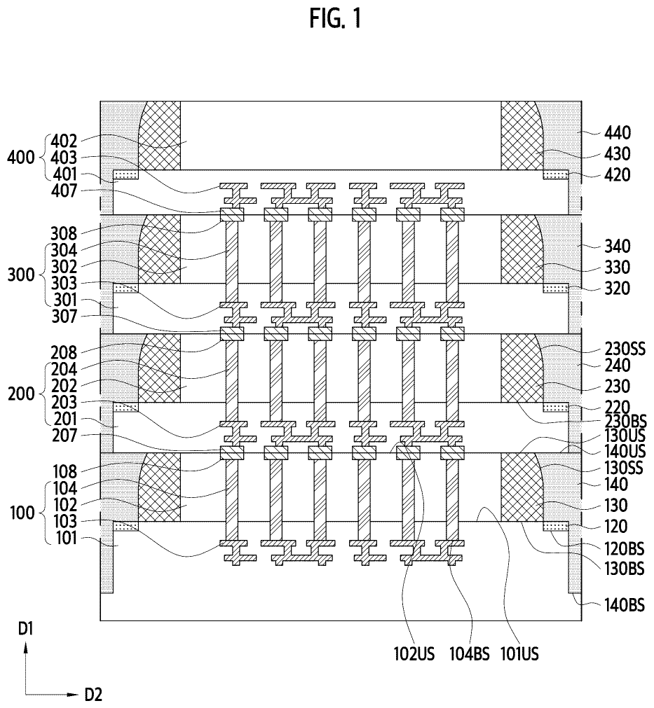

FIG. 1 is an example drawing for describing a semiconductor package according to example embodiments.

Referring to FIG. 1, the semiconductor package (e.g., chip stack) according to example embodiments may include a first chip 100, a second chip 200, a third chip 300, and a fourth chip 400.

According to example embodiments, the first chip 100, the second chip 200, the third chip 300, and the fourth chip 400 may be stacked (e.g., laminated) in a first direction D1. As an example, the first direction D1 may be a direction perpendicular to an upper surface 101US of a first front substrate 101 of the first chip 100. The upper surface 101US of the first front substrate 101 may be a surface on which the first front substrate 101 is in contact with a first rear substrate 102. Note that the term “substrate” may denote a base substrate (e.g., an initial semiconductor substrate forming the base of the wafer in the final wafer product, such as a bulk semiconductor substrate (e.g., formed of crystalline silicon), a silicon on insulator (SOI) substrate, etc.) or a stack structure including such a base substrate and layers formed on the base substrate (e.g., interconnected patterned conductive layers separated by insulating layers formed on the base substrate).

For example, the first chip 100, the second chip 200, the third chip 300, and the fourth chip 400 may form a high bandwidth memory (HBM). According to other example embodiments, the first chip 100, the second chip 200, the third chip 300, and the fourth chip 400 may belong to an integrated circuit (IC) into which hundreds of millions of semiconductor devices are integrated in one chip. As an example, the first chip 100 may be a volatile memory chip such as a dynamic random-access memory (DRAM) or a static random-access memory (SRAM). The first chip 100, the second chip 200, the third chip 300, and the fourth chip 400 may be a non-volatile memory chip such as a read-only memory (ROM) or a flash memory. As another example, the first chip 100 may be a logic chip. The first chip 100, the second chip 200, the third chip 300, and the fourth chip 400 may be a microprocessor, an analog device, a digital signal processor, or an application processor (AP). The first chip 100 may be an application processor (AP) such as a central processing unit (CPU), a graphics processing unit (GPU), a field-programmable gate array (FPGA), a digital signal processor, an encryption processor, a microprocessor, or a microcontroller, but these are merely examples, and the present invention is not limited thereto.

According to example embodiments, the first chip 100 may include the first front substrate 101, the first rear substrate 102, a first device layer 103, and a first through via 104. In some examples, both first front substrate 101 and first rear substrate 102 may include circuitry (e.g., interconnected logic circuits each formed of interconnected transistors). In other examples, the first rear substrate 102 may not include logic circuits or other active devices (e.g., transistors).

According to example embodiments, the first front substrate 101 may be disposed below the first rear substrate 102 in the first direction D1. As an example, the first front substrate 101 may include a base substrate, such as bulk crystalline semiconductor or silicon-on-insulator (SOI), and additional layers formed thereon (e.g. patterned conductive layers separated by insulating layers). As another example, the base substrate of the first front substrate 101 may be a bulk silicon substrate. As still another example, the base substrate of the first front substrate 101 may be bulk silicon germanium, silicon germanium on insulator (SGOI), indium antimonide, lead telluride compound, indium arsenide, indium phosphide, gallium arsenide, or gallium antimonide, but these are merely examples, and the present invention is not limited thereto.

According to other example embodiments, the first front substrate 101 may include conductive regions, such as wells doped with impurities or a structure (e.g., semiconductor fins) doped with impurities. The first front substrate 101 may have various device isolation structures such as shallow trench isolation (STI) that isolate these conductive regions from one another.

According to example embodiments, the first front substrate 101 may include the first device layer 103. The first device layer 103 may include a plurality of individual devices of various types formed with the first front substrate 101, and patterned conductive (e.g., metal) layers and patterned insulating films (e.g., inter-layer insulating films) formed on the base substrate of the first front substrate 101. The individual devices may include various microelectronic devices, as an example, a metal-oxide-semiconductor field effect (MOSFET) transistors that are interconnected to form complementary metal-oxide-semiconductor (CMOS) circuits (e.g., logic gates), a system large scale integration (LSI) device, a flash memory, a dynamic random-access memory (DRAM), a static random access memory (SRAM), an electrically erasable programmable read-only memory (EEPROM), a phase-change random access memory (PRAM), a magnetic random access memory (MRAM), a resistive random access memory (RRAM), an image sensor such as a CMOS imaging sensor (CIS), a micro-electro-mechanical system (MEMS), an active device, a passive device, and the like.

According to example embodiments, the individual devices of the first device layer 103 may be electrically connected to and/or formed with the conductive regions formed within the first front substrate 101. The individual devices of the first device layer 103 may be electrically separated from other neighboring individual devices by insulating films. The first front substrate 101 may include interconnections formed of interconnected elements of the patterned conductive layers electrically connecting various ones of the plurality of individual devices of the first device layer 103, or electrically connecting the individual devices to one or more first through vias 104 to be electrically connected (e.g., communicate information and/or power) to external sources, such as other chips within the semiconductor package and/or external to the semiconductor package.

According to example embodiments, the first rear substrate 102 may be disposed on the first front substrate 101 in the first direction D1. The first rear substrate 102 may be disposed between the first front substrate 101 and a second front substrate 201. In a second direction D2, a width of the first rear substrate 102 may be smaller than that of the first front substrate 101. The second direction D2 may be a direction crossing the first direction D1. The second direction D2 may be a direction parallel to the upper surface 101US of the first front substrate 101. The first rear substrate 102 may be penetrated by the first through via 104. A side surface of the first rear substrate 102 may be surrounded by a first spacer film 130.

According to example embodiments, the first rear substrate 102, as an example, may be a bulk crystalline semiconductor substrate or silicon-on-insulator (SOI). For example, the first rear substrate 102 may be a bulk silicon substrate. As still another example, the first rear substrate 102 may be bulk silicon germanium, silicon germanium on insulator (SGOI), indium antimonide, lead telluride compound, indium arsenide, indium phosphide, gallium arsenide, or gallium antimonide, but these are merely examples.

According to example embodiments, the first rear substrate 102 may include a conductive region, such as a well doped with impurities or a structure doped with impurities. The first rear substrate 102 may have various device isolation structures such as a shallow trench isolation (STI).

According to example embodiments, the first through via 104 may penetrate the first rear substrate 102. For example, the first through via 104 may be partially inserted into the first front substrate 101. In another example, the first through via 104 may penetrate fully through the first front substrate 101 to extend and be exposed at the bottom surface of the first front substrate 101. The first through via 104 may be connected to the first device layer 103 within the first front substrate 101. The first through via 104 may be electrically connected devices of device layer 103 by the interconnection structure within the first front substrate 101.

According to example embodiments, the first through via 104 may include a barrier film formed on a surface of a cylindrical shape and an embedded conductive layer filling an inside of the barrier film. The barrier film may include at least one of titanium (Ti), titanium nitride (TiN), tantalum (Ta), tantalum nitride (TaN), ruthenium (Ru), carbon monoxide (Co), manganese (Mn), tungsten nitride (WN), nickel (Ni), and nickel boride (NiB), but these are merely examples. The embedded conductive layer may include at least one of copper alloys such as copper (Cu), copper-tin alloy (CuSn), copper-magnesium alloy (CuMg), copper-nickel alloy (CuNi), copper-zinc alloy (CuZn), copper-palladium alloy (CuPd), copper-gold alloy (CuAu), copper-rhenium alloy (CuRe), and copper-tungsten alloy (CuW), or tungsten (W), tungsten (W) alloy, nickel (Ni), ruthenium (Ru), and cobalt (Co), but these are merely examples.

According to example embodiments, a first chip upper bonding pad 108 (e.g., a chip pad) may be disposed on the first through via 104. The first chip upper bonding pad 108 constitutes an electrical terminal of the chip 100 and may be connected to the first through via 104 to communicate (power, signals, etc.) with the devices of the chip 100. The first chip upper bonding pad 108 may be disposed within the first rear substrate 102. The first chip upper bonding pad 108 may be exposed to an upper surface of the first rear substrate 102. The first chip upper bonding pad 108 may include a conductive material. As an example, the first chip upper bonding pad 108 may include copper (Cu), aluminum (Al), silver (Ag), tin (Sn), gold (Au), nickel (Ni), lead (Pb), titanium (Ti), or an alloy thereof, but these are merely examples.

In FIG. 1, the first chip upper bonding pad 108 is illustrated as disposed within the first rear substrate 102, but example embodiments of the present disclosure are not limited thereto. As an example, the first chip upper bonding pad 108 may be disposed on the first rear substrate 102. A passivation film may be disposed on the first rear substrate 102 and the first chip upper bonding pad 108 may penetrate the passivation film and be connected to the first through via 104.

According to example embodiments, the first front substrate 101 of the first chip 100 may include a first blocking film 120, which may enable first spacer film 130 to be selectively formed on the side surfaces of the chips. The first blocking film 120 may be disposed on the upper surface 101US of the first front substrate. The first blocking film 120 may be inserted and disposed into the first front substrate 101 from the upper surface 101US of the first front substrate.

According to example embodiments, the first blocking film 120 may be disposed at the first front substrate 101. The first blocking film 120 may be exposed at the upper surface 101US of the first front substrate. The first blocking film 120 may not be in contact with the first spacer film 130. The first blocking film 120 and the first spacer film 130 may not overlap with each other in the first direction D1. A depth of the first blocking film 120 within the first front substrate 101 (e.g., along the first direction D1) may be smaller than a depth of the first through via 104. For example, a lower surface 120BS of the first blocking film 120 may be disposed above a lower surface 104BS of the first through via 104. The lower surface 120BS of the first blocking film may be disposed closer to the upper surface 101US of the first front substrate than the lower surface 104BS of the first through via 104.

According to example embodiments, the first blocking film 120 may be hydrophobic. As an example, the first blocking film 120 may be a fluorocarbon-based film. For example, the first blocking film 120 may repel first pre-spacer film 130P during the formation of first spacer film 130, as described below.

According to example embodiments, the first spacer film 130 may cover the side surface of the first rear substrate 102. A function of the first spacer film 130 may be to protect the first chip 100 from fracture risk (e.g., during wafer grinding), as described herein. The first spacer film 130 may be disposed on the first front substrate 101. The first spacer film 130 may be disposed below the second chip 200. The first spacer film 130 may not be in contact with the first blocking film 120. The first spacer film 130 may not overlap with the first blocking film 120 in the first direction D1. The first spacer film 130 may cover at least a portion of the upper surface 101US of the first front substrate. For example, the first spacer film 130 may cover the upper surface 101US of the first front substrate between the first rear substrate 102 and the first blocking film 120. A lower surface 130BS of the first spacer film may not be in contact with the first blocking film 120.

According to example embodiments, a side surface 130SS of the first spacer film may include a curved surface. The side surface 130SS of the first spacer film may be curved to be convex outward. The side surface 130SS of the first spacer film may be curved to be convex from the side surface of the first rear substrate 102 towards a first molding film 140. A width of the first spacer film 130 may not be constant in the second direction D2. As an example, the width of the first spacer film 130 in the second direction D2 may decrease closer to the second chip 200. A width of the lower surface 130BS of the first spacer film in the second direction D2 may be greater than a width of an upper surface 130US of the first spacer film.

According to example embodiments, the first molding film 140 may cover the side surface 130SS of the first spacer film. The first molding film 140 may cover at least a portion of a side surface of the first front substrate 101. The first molding film 140 may overlap with at least a portion of the first front substrate 101 in the second direction D2. The first molding film 140 may cover the first blocking film 120. The first molding film 140 may be disposed below the second chip 200.

According to example embodiments, the first molding film 140 may be in contact with a second molding film 240, which may belong to the second chip 200. The first molding film 140 may be disposed below the second molding film 240 in the first direction D1. The first molding film 140 may be bonded to the second molding film 240.

According to example embodiments, each of the first spacer film 130 and the first molding film 140 may include a polymer such as resin. The first spacer film 130 and the first molding film 140 may include materials different from each other. The first spacer film 130 may include and/or may be formed entirely of a first resin. The first molding film 140 may include and/or may be formed entirely of a second resin that is different from the first resin. The second resin included in the first molding film 140 may have higher adhesive strength than that of the first resin included in the first spacer film 130.

According to example embodiments, an upper surface 102US of the first rear substrate, the upper surface 130US of the first spacer film, and an upper surface 140US of the first molding film may be disposed on the same plane. A lower surface 140BS of the first molding film may be disposed lower than the lower surface 130BS of the first spacer film and the upper surface 101US of first front substrate 101.

According to example embodiments, the second chip 200 may be disposed on (e.g., above) the first chip 100 in the first direction D1. The second chip 200 may include the second front substrate 201, a second rear substrate 202, a second device layer 203 and a second through via 204.

According to example embodiments, the second front substrate 201 may be disposed on the first rear substrate 102. The second front substrate 201 may be disposed between the first rear substrate 102 and the second rear substrate 202, which in turn may be disposed below a third front substrate 301. A second chip lower bonding pad 207 may be disposed within the second front substrate 201. The second chip 200 may be electrically connected to the first chip 100 through the second chip lower bonding pad 207.

According to example embodiments, the second front substrate 201 may be disposed on the first spacer film 130 and the first molding film 140. The second front substrate 201 may cover at least a portion of the upper surface 130US of the first spacer film and the upper surface 140US of the first molding film. Since being substantially identical to a description of the first front substrate 101 and the first device layer 103, a description of the second front substrate 201 and the second device layer 203 separate from the above description will be omitted.

According to example embodiments, the second rear substrate 202 may be disposed on the second front substrate 201 in the first direction D1. The second rear substrate 202 may be disposed between the second front substrate 201 and the third front substrate 301.

According to example embodiments, the second chip lower bonding pad 207 may be disposed within the second front substrate 201. The second chip lower bonding pad 207 may be connected to the second device layer 203 within the second front substrate 201. The second chip lower bonding pad 207 may be exposed to a lower surface of the second front substrate 201. The second chip lower bonding pad 207 may be disposed on, and may be in contact with, the first chip upper bonding pad 108. The second chip 200 and the first chip 100 may be connected through hybrid bonding.

According to example embodiments, the second chip lower bonding pad 207 may include a conductive material. As an example, the second chip lower bonding pad 207 may include copper (Cu), aluminum (Al), silver (Ag), tin (Sn), gold (Au), nickel (Ni), lead (Pb), titanium (Ti), or an alloy thereof, but these are merely examples. Although in FIG. 1 the second chip lower bonding pad 207 is shown as being disposed within the second front substrate 201, example embodiments of the present disclosure are not limited thereto. As an example, the second chip lower bonding pad 207 may be disposed below the second front substrate 201. A passivation film covering the lower surface of the second front substrate 201 may be disposed, and the second chip lower bonding pad 207 may penetrate the passivation film and be connected to the first chip upper bonding pad 108. Since being substantially identical to descriptions of the first rear substrate 102, the first through via 104, and the first chip upper bonding pad 108 respectively, descriptions of the second rear substrate 202, the second through via 204, and a second chip upper bonding pad 208 separate from the above description will be omitted.

According to example embodiments, the second front substrate 201 of the second chip 200 may include a second blocking film 220. The second blocking film 220 may be disposed on an upper surface of the second front substrate 201. The second blocking film 220 may be inserted into the second front substrate 201 from the upper surface of the second front substrate 201. The second blocking film 220 may not be in contact with a second spacer film 230. The second blocking film 220 and the second spacer film 230 may not overlap with each other in the first direction D1.

According to example embodiments, the second blocking film 220 may be hydrophobic. As an example, the second blocking film 220 may be a fluorocarbon-based film. For example, the second blocking film 220 may repel second spacer film 230 during its formation. The second blocking film 220 may include and/or may be formed entirely of a material identical to that of the first blocking film 120.

According to example embodiments, the second spacer film 230 may cover at least a portion of a side surface of the second chip 200. The second spacer film 230 may cover a side surface of the second rear substrate 202. The second spacer film 230 may be disposed on the second front substrate 201, and may be disposed below the third chip 300. The second spacer film 230 may not be in contact with the second blocking film 220. The second spacer film 230 may not overlap with the second blocking film 220 in the first direction D1.

According to example embodiments, the second spacer film 230 may overlap with at least a portion of the first spacer film 130 in the first direction D1. The second spacer film 230 may not be in contact with the first spacer film 130 in the first direction D1. For example, the second spacer film 230 may be spaced apart from the first spacer film 130 with the second front substrate 201 interposed in between.

According to example embodiments, a side surface 230SS of the second spacer film may include a curved surface. The side surface 230SS of the second spacer film may be curved to be convex outward. The side surface 230SS of the second spacer film may be curved to be convex toward the second molding film 240 from the side surface of the second rear substrate 202. A width of the second spacer film 230 may not be constant in the second direction D2. As an example, the width of the spacer film 230 in the second direction D2 may increase closer to the first chip 100. A width of a lower surface 230BS of the second spacer film in the second direction D2 may be greater than a width of the upper surface 130US of the first spacer film.

According to example embodiments, the second molding film 240 may cover the side surface 230SS of the second spacer film. The second molding film 240 may cover at least a portion of a side surface of the second front substrate 201. The second molding film 240 may overlap with at least a portion of the second front substrate 201 in the second direction D2. The second molding film 240 may cover the second blocking film 220. The second molding film 240 may be disposed below the third chip 300.

According to example embodiments, the second molding film 240 may be in contact with the first molding film 140. The second molding film 240 may be disposed between the first molding film 140 and a third molding film 340 of the third chip 300 in the first direction D1. The second molding film 240 may be bonded with the first molding film 140 and the third molding film 340.

According to example embodiments, each of the second spacer film 230 and the second molding film 240 may include a polymer such as resin. The second spacer film 230 and the second molding film 240 may include materials different from each other. The second spacer film 230 may include and/or may be formed entirely of the first resin. The second molding film 240 may include and/or may be formed entirely of the second resin, which is different from the first resin. The second spacer film 230 may include and/or may be formed entirely of a material identical to that of the first spacer film 130. The second molding film 240 may include and/or may be formed entirely of a material identical to that of the first molding film 140.

Since being substantially identical to a description of the first spacer film 130 and the first molding film 140, a description of the second spacer film 230 and the second molding film 240 separate from the above description will be omitted.

According to example embodiments, the third chip 300 may include the third front substrate 301, a third rear substrate 302, a third device layer 303, and a third through via 304. The third chip 300 may include a third blocking film 320 and be covered by a third spacer film 330 and the third molding film 340. The fourth chip 400 may include a fourth front substrate 401, a fourth rear substrate 402, and a fourth device layer 403. The fourth chip 400 may include a fourth blocking film 420 and be covered by a fourth spacer film 430 and a fourth molding film 440. The fourth chip 400 may not include a through via, unlike the first chip 100, second chip 200, and third chip 300. Since being substantially identical to a description of the first chip 100 and the second chip 200, a description of the third chip 300 and the fourth chip 400 will be omitted.

According to example embodiments, the first chip 100, the second chip 200, the third chip 300, and the fourth chip 400 may be connected to each other by bonding front and rear surfaces thereof. As an example, a rear surface of the first chip 100 and a front surface of the second chip 200 may be bonded. The upper surface 102US of the first rear substrate which is the rear surface of the first chip 100 and the lower surface of the second front substrate 201 which is the front surface of the second chip 200 may be bonded. In the same manner, a rear surface of the second chip 200 and a front surface of the third chip 300, and a rear surface of the third chip 300 and a front surface of the fourth chip 400, may be bonded.

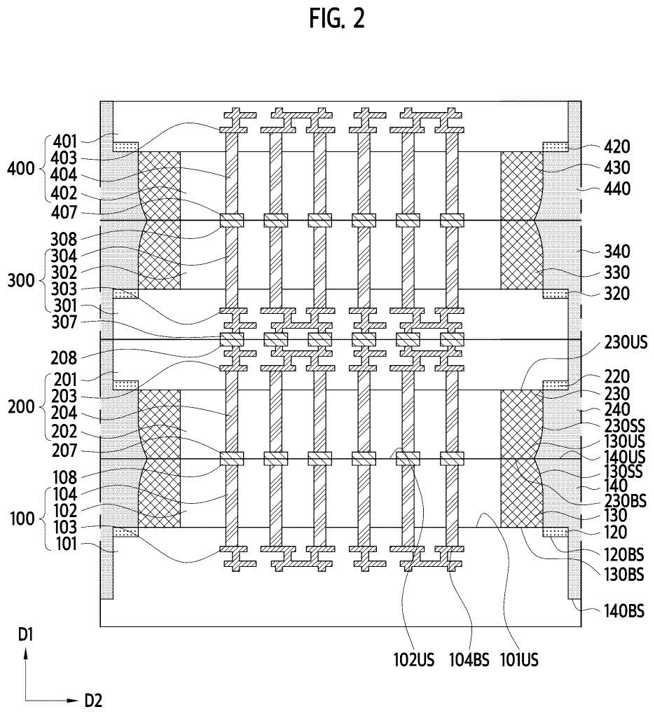

FIG. 2 is an example drawing for describing a semiconductor package (e.g., chip stack) according to other example embodiments. To describe the semiconductor package according to some other example embodiments, details different from those described above with reference to FIG. 1 will be mainly provided.

Referring to FIG. 2, the first spacer film 130 may be in contact with the second spacer film 230. The first spacer film 130 may be disposed below the second spacer film 230 in the first direction D1.

Alternatively, according to example embodiments other than the embodiment of FIG. 1, the first chip 100 and the second chip 200 may be connected to each other by bonding rear surfaces thereof. As an example, a rear surface of the first chip 100 and a rear surface of the second chip 200 may be bonded. The upper surface 102US of a first rear substrate which is the rear surface of the first chip 100 and a lower surface of the second rear substrate 202 which is the rear surface of the second chip 200 may also be bonded. The first chip 100 and the second chip 200 may be bonded in a symmetrical structure (e.g., having mirror symmetry) in the first direction D1. The first chip upper bonding pad 108 of the first chip 100 and a second chip lower bonding pad 207 of the second chip 200 may be in contact with each other, so that the first chip 100 and the second chip 200 may be electrically connected.

In addition, according to the example embodiments of FIG. 2, the second chip 200 and the third chip 300 may be connected to each other by bonding front surfaces thereof. As an example, a front surface of the second chip 200 and a front surface of the third chip 300 may be bonded. An upper surface of the second front substrate 201 which is the front surface of the second chip 200 and a lower surface of the third front substrate 301 which is the front surface of the third chip 300 may be bonded. The second chip 200 and the third chip 300 may be bonded in a symmetrical structure (e.g., having mirror symmetry) in the first direction D1. The second chip upper bonding pad 208 of the second chip 200 and a third chip lower bonding pad 307 of the third chip 300 may be in contact with each other, so that the second chip 200 and the third chip 300 may be electrically connected.

According to example embodiments, the second chip upper bonding pad 208 may be disposed within the second front substrate 201. The second chip upper bonding pad 208 may be connected to the second device layer 203 within the second front substrate 201. The second chip upper bonding pad 208 may be exposed to the upper surface of the second front substrate 201.

According to example embodiments, the third chip lower bonding pad 307 may be disposed within the third front substrate 301. The third chip lower bonding pad 307 may be connected to the third device layer 303 within the third front substrate 301. The third chip lower bonding pad 307 may be exposed to the lower surface of the third front substrate 301.

In addition, according to the example embodiments of FIG. 2, the third chip 300 and the fourth chip 400 may be connected to each other by bonding rear surfaces. As an example, a rear surface of the third chip 300 and a rear surface of the fourth chip 400 may be bonded. An upper surface of the third rear substrate 302 which is the rear surface of the third chip 300 and a lower surface of the fourth rear substrate 402 which is the rear surface of the fourth chip 400 may be bonded. The third chip 300 and the fourth chip 400 may be bonded in a symmetrical structure (e.g., having mirror symmetry) in the first direction D1. A third chip upper bonding pad 308 of the third chip 300 and a fourth chip lower bonding pad 407 of the fourth chip 400 may be in contact with each other, so that the third chip 300 and the fourth chip 400 may be electrically connected.

According to example embodiments, the third chip upper bonding pad 308 may be disposed within the third rear substrate 302. The third chip upper bonding pad 308 may be connected to the third through via 304 within the third rear substrate 302. The third chip upper bonding pad 308 may be exposed to the upper surface of the third rear substrate 302.

According to example embodiments, the fourth chip lower bonding pad 407 may be disposed within the fourth rear substrate 402. The fourth chip lower bonding pad 407 may be connected to a fourth through via 404 within the fourth rear substrate 402. The fourth chip lower bonding pad 407 may be exposed to the lower surface of the fourth rear substrate 402.

According to example embodiments, the second front substrate 201 of the second chip 200 may include the second blocking film 220. The second blocking film 220 may be disposed on a lower surface of the second front substrate 201. The second blocking film 220 may be inserted into the second front substrate 201 from the lower surface of the second front substrate 201. The second blocking film 220 may not be in contact with the second spacer film 230. The second blocking film 220 and the second spacer film 230 may not overlap with each other in the first direction D1. The second blocking film 220 and the first blocking film 120 may face each other in the first direction D1.

According to example embodiments, the second spacer film 230 may be disposed below the second front substrate 201. The second spacer film 230 may be connected to the first spacer film 130 in the first direction D1. The second spacer film 230 may be in contact with the first spacer film 130. The lower surface 230BS of the second spacer film and the upper surface 130US of the first spacer film may be in contact with each other. A width of the lower surface 230BS of the second spacer film and a width of the upper surface 130US of the first spacer film in the second direction D2 may be equal. However, the example embodiment of the present disclosure is not limited thereto. The width of the lower surface 230BS of the second spacer film and the width of the upper surface 130US of the first spacer in contact with each other may differ from each other.

According to example embodiments, the side surface 230SS of the second spacer film may include a curved surface. A width of the second spacer film 230 in the second direction D2 may decrease closer to the first chip 100. The width of the lower surface 230BS of the second spacer film may be smaller than a width of an upper surface 230US of the second spacer film.

According to example embodiments, the second chip lower bonding pad 207 may be disposed within the second rear substrate 202. The second chip lower bonding pad 207 may be connected to the second through via 204 within the second rear substrate 202. The second chip lower bonding pad 207 may be exposed to the lower surface of the second rear substrate 202.

According to example embodiments, the first through via 104 of the first chip 100 and the second through via 204 of the second chip 200 may be connected to each other through the first chip upper bonding pad 108 and the second chip lower bonding pad 207.

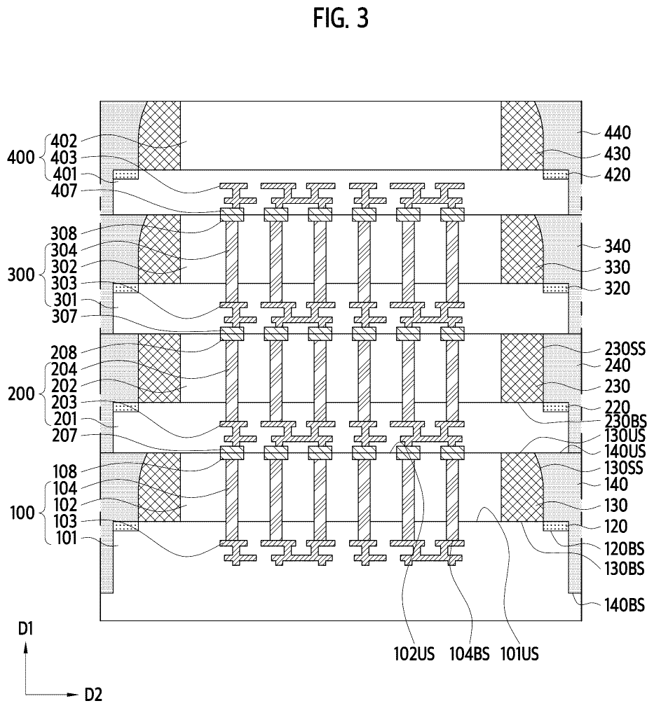

FIG. 3 is an example drawing for describing a semiconductor package (e.g., chip stack) according to still other example embodiments. To describe the semiconductor package according to still other example embodiments, details different from those described above with reference to FIG. 1 will be mainly provided.

Referring to FIG. 3, at least a portion of a plurality of spacer films 130, 230, 330, and 430 may not have a curved side surface. As an example, the side surface 230SS of a second spacer film may have a flat surface instead of a curved surface. A width of an upper surface and the lower surface 230BS of the second spacer film 230 in the second direction D2 may be identical.

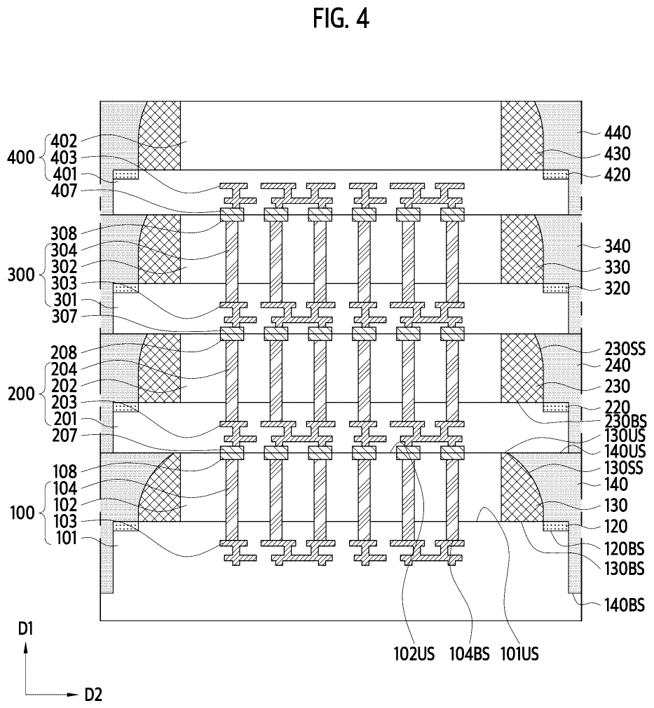

FIG. 4 is an example drawing for describing a semiconductor package (e.g., chip stack) according to still other example embodiments. To describe the semiconductor package according to still other example embodiments, details different from those described above with reference to FIG. 1 will be mainly provided.

Referring to FIG. 4, shapes of curved surfaces of the plurality of spacer films 130, 230, 330, and 430 may be different from each other. As an example, the side surface 130SS of a first spacer film may be curved further than the side surface 230SS of a second spacer film. A minimum width of the first spacer film 130 and a minimum width of the second spacer film 230 in the second direction D2 may differ from each other. The minimum width of the first spacer film 130 in the second direction D2 may be a width of the upper surface 130US of the first spacer film. The minimum width of the second spacer film in the second direction D2 may be a width of an upper surface of the second spacer film 230. The width of the upper surface 130US of the first spacer film in the second direction D2 may be smaller than the width of the upper surface of the second spacer film 230.

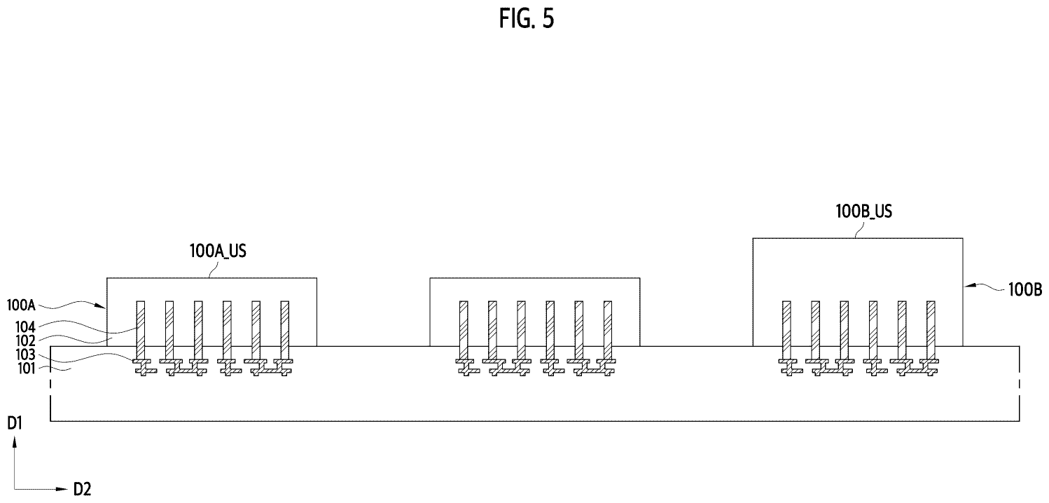

FIGS. 5 through 12 are example drawings describing an intermediate process for explaining a method of fabricating a semiconductor package according to the example embodiment illustrated in FIG. 1. It will be understood that a “chip” may refer to a portion of a wafer that has been separated (e.g., cut or diced) from the wafer or will be separated from the wafer in later steps. “Undiced” and “diced” may be used to identify the state of such chips (i.e., whether still part of the larger wafer or separated from the wafer).

Referring to FIG. 5, a plurality of first rear substrates 102 may be formed on (e.g., attached to) the first front substrate 101. The first front substrate 101 may be a wafer. The first device layer 103 may be part of the first front substrate 101. The plurality of first rear substrates 102 may be a plurality of diced chips (separated after sawing from a wafer). As an example, the first front substrate 101 and the first rear substrates 102 may be bonded together.

According to example embodiments, heights in the first direction D1 of the plurality of the first rear substrates 102 disposed on the first front substrate 101 may differ from each other. As an example, a first chip 100A with a first upper surface 100A_US that has a first height may be formed by the first front substrate 101 and one of the first rear substrates 102. A second chip 100B with a second upper surface 100B_US that has a second height that is greater than the first height may be formed by the first front substrate 101 and another one of the first rear substrates 102. In some examples, first front substrate 101, first rear substrates 102, first chip 100A, and/or second chip 100B may each form an integrated circuit (e.g., include circuitry of interconnected logic gates that are formed of interconnected transistors). Chips 100A and 100B may be integrated with front substrate 101 at the wafer level (i.e., form a wafer with the front substrate 101) and thus form part of a larger chip (e.g., chip 100) when cut from the wafer. In some examples, chip 100B may not be separated from one or more of chips 100A and thus sawing and the related processes may be performed with respect to sets of chips 100A and 100B.

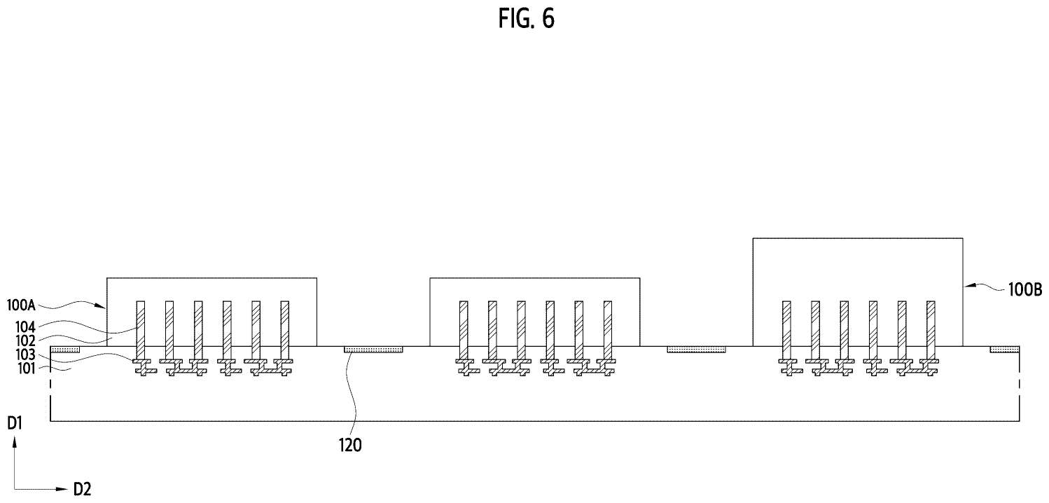

Referring to FIG. 6, the first blocking film 120 may be formed on the first front substrate 101. The first blocking film 120 may be formed between a plurality of first rear substrates 102. The first blocking film 120 may be deposited on the first front substrate 101 using a mask. The first blocking film 120 may include and/or may be formed entirely of a hydrophobic material.

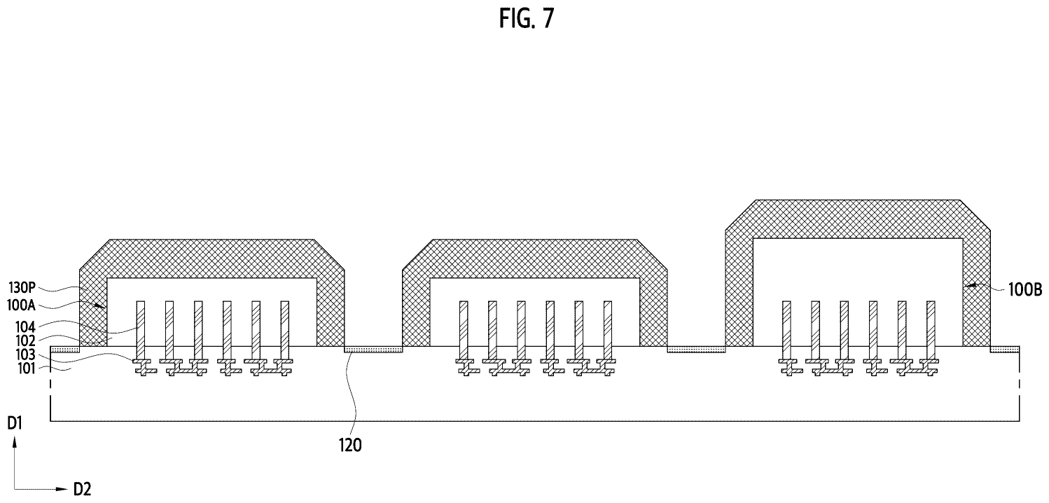

Referring to FIG. 7, a first pre-spacer film 130P may be formed on the plurality of first rear substrates 102. The first pre-spacer film 130P may be initially formed (e.g., deposited) with a particular shape before formation of the first spacer film 130 (of FIG. 1). Hereinafter the word “pre” may indicate a structure appearing during an intermediate process before being formed into a final structure. The first pre-spacer film 130P may cover the plurality of first rear substrates 102.

According to example embodiments, the first pre-spacer film 130P may be formed on the plurality of first rear substrates 102 by using a droplet scheme (e.g., by depositing droplets of the material that forms the first pre-spacer film 130P). The first pre-spacer film 130P may include and/or may be formed entirely of a resinous material. The first pre-spacer film 130P may be formed between first blocking films 120. The first pre-spacer film 130P and the first blocking film 120 may include respective repulsive materials that repel each other, and therefore may not come into contact with one another. Accordingly, the first pre-spacer film 130P may be selectively formed on a side surface of the first rear substrate 102 between the first blocking films 120.

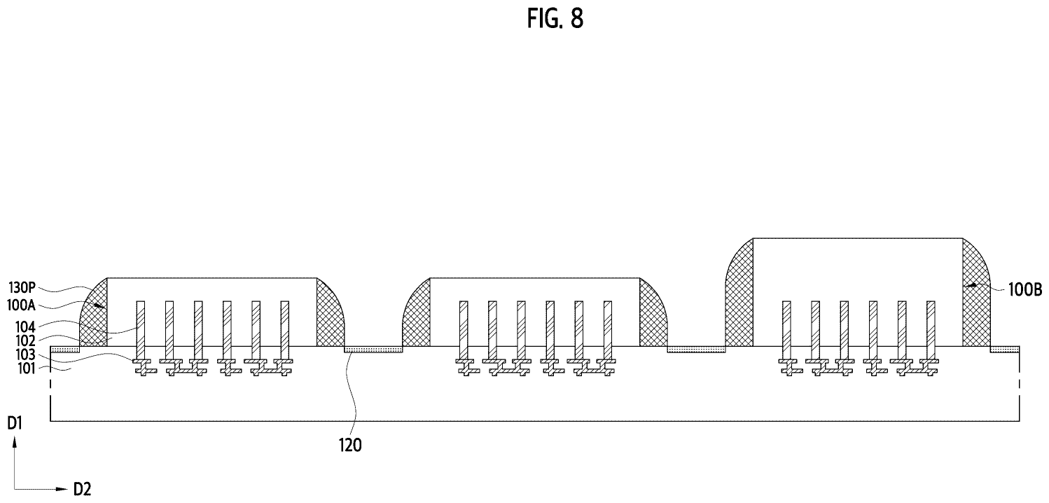

Referring to FIG. 8, the first pre-spacer film 130P may be treated with heat. The first pre-spacer film 130P covering an upper surface of the first rear substrate 102 may be removed. However, example embodiments of the present disclosure are not limited thereto. In some examples, the first pre-spacer film 130P covering the upper surface of the first rear substrate 102 may not be removed and may remain on the first rear substrate 102.

According to example embodiments, while being formed on the first rear substrate 102 by using the droplet scheme and treated with the heat, the first pre-spacer film 130P may have a curved side surface. A side surface of the first pre-spacer film 130P covering the first rear substrate 102 which has a relatively greater height may include a portion curved less than a side surface of the first pre-spacer film 130P covering the first rear substrate 102 which has a relatively smaller height. As an example, a portion of a side surface of the first pre-spacer film 130P covering a side surface of the second chip 100B may be flat and another portion thereof may be curved. A side surface of the first pre-spacer film 130P covering a side surface of the first chip 100A may be curved without any flat surface. However, example embodiments of the present disclosure are not limited thereto. The side surface of the first pre-spacer film 130P covering the side surface of the second chip 100B may be a completely curved surface, and the side surface of the first pre-spacer film 130P covering the side surface of the first chip 100A may also include a partially flat surface. In general, the curvature of the side surface of the first pre-spacer film 130P may be sufficient for the first pre-spacer film 130P to reach the upper surface of the first front substrate 101 without covering the first blocking films 120.

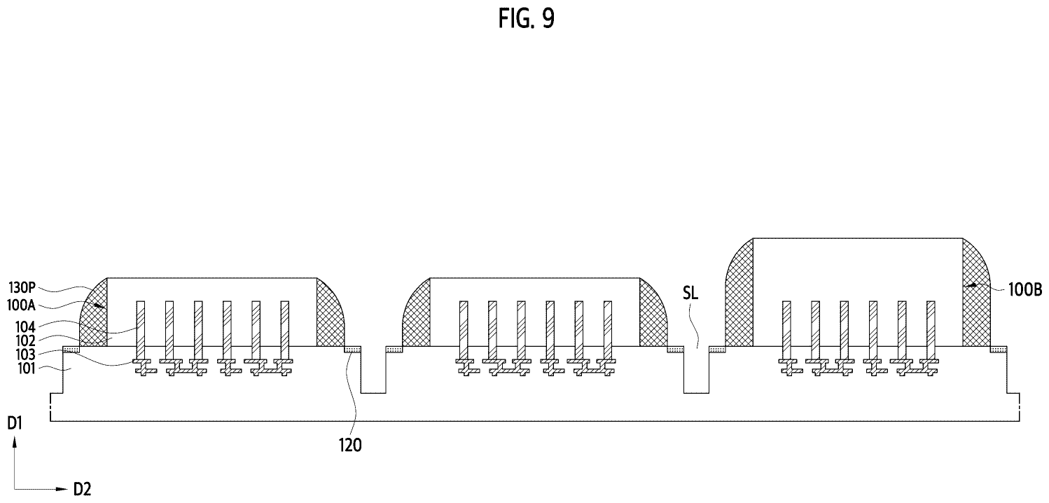

Referring to FIG. 9, a sawing line pattern SL may be formed on the first front substrate 101. The sawing line pattern SL may have a trench structure which is inserted into the first front substrate 101 from a surface thereof. The sawing line pattern SL may not penetrate the first front substrate 101 completely. The sawing line pattern SL may be formed between the plurality of first rear substrates 102. The sawing line pattern SL between the undiced chips may comprise areas of the wafer in which no circuits (e.g., no transistors) are formed and/or no circuits (e.g., no transistors) are formed that are part of the integrated circuits of the undiced chips. In some examples, the cutting may be performed in two horizontal directions (e.g., along the second direction D2 and along a horizontal direction perpendicular to D2) to provide a grid shape of cuts. Accordingly, in this case, the sawing line pattern SL may form a grid shape.

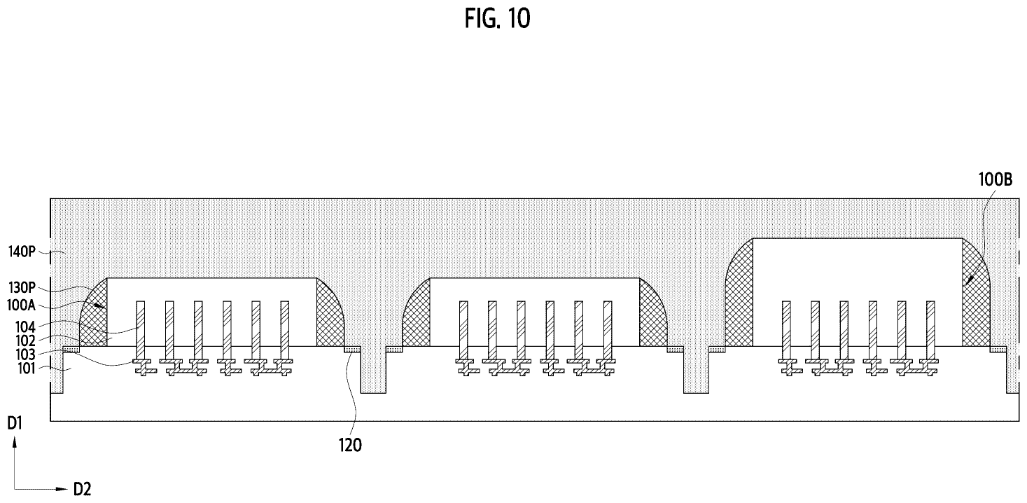

Referring to FIG. 10, a first pre-molding film 140P may be formed on the first front substrate 101. The first pre-molding film 140P may cover the plurality of first rear substrates 102. The first pre-molding film 140P may cover side surfaces of a plurality of first pre-spacer films 130P covering the plurality of first rear substrates 102. The first pre-molding film 140P may fill the trench of the sawing line pattern SL (of FIG. 9). The first pre-molding film 140P may include a resinous material, such as resin and/or epoxy mold compound (EMC). The first pre-molding film 140P may include a resinous material different from that included in the first pre-spacer film 130P.

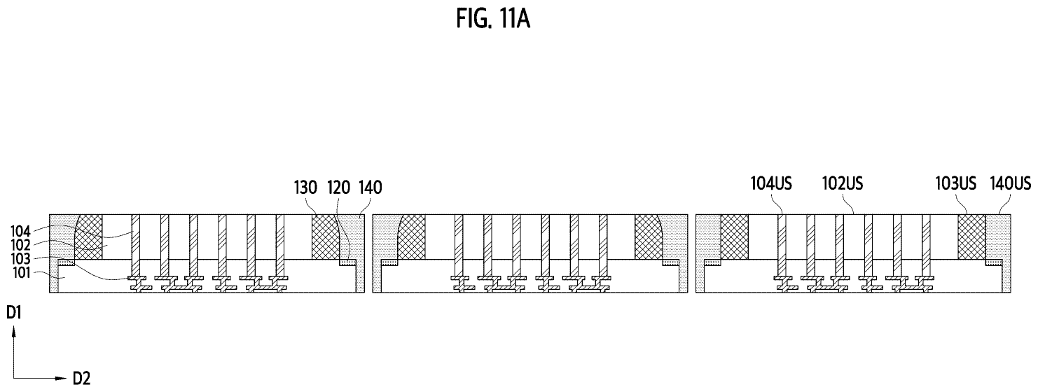

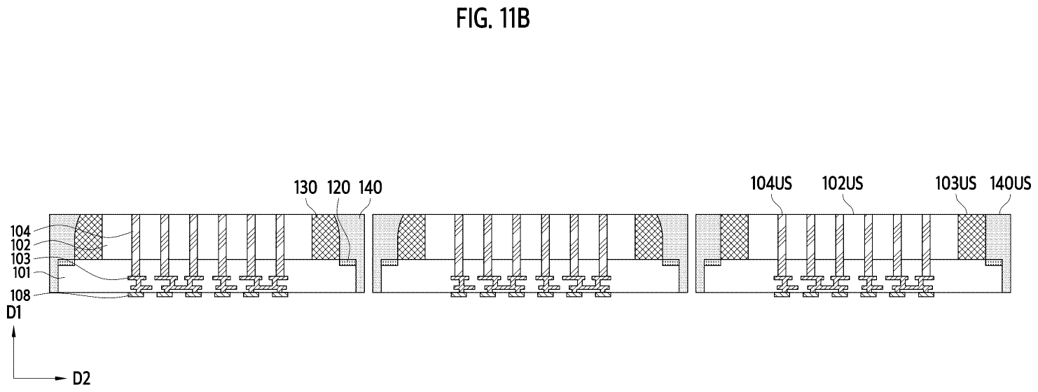

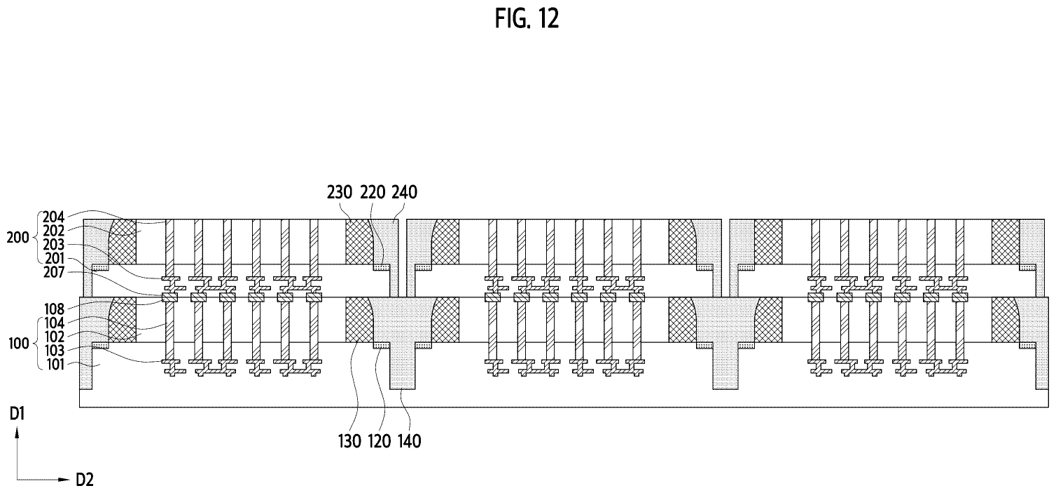

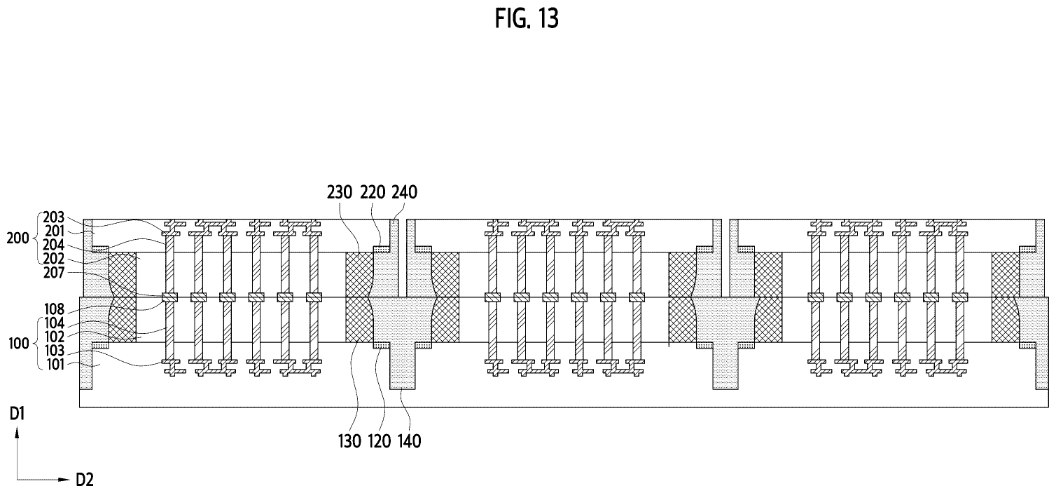

FIGS. 11A and 11B illustrate grinding of first chip 100A and second chip 100B. In some embodiments, FIG. 11A may show first chip 100A and second chip 100B ground to the same height but not separated from each other, while FIG. 11B may show the chips divided as well as ground. In some embodiments, as described in the examples of FIGS. 12-13 below, the undivided chips of FIG. 11A may be placed at the bottom of the chip stack, while the divided chips of FIG. 11B may be stacked above the chips of FIG. 11A.

Referring to FIG. 11A, chip pads 108 may be added, for example at the top of first chip 100A and second chip 100B. In addition, grinding of first chip 100A and second chip 100B may be performed. For example, first chip 100A and second chip 100B may be ground to the same height but not separated from each other, as shown in FIG. 11A. The case of optional backside grinding to the bottom of sawing line pattern SL, so as to obtain discrete substrates 101, is described in the example of FIG. 11B.

Referring to FIG. 11B, a plurality of chips may be formed by cutting to divide the first front substrate 101 in the second direction D2 and grinding (e.g., backside grinding) the first front substrate 101 and the first rear substrate 102. The first front substrate 101 may be cut along the sawing line pattern SL (of FIG. 9), for example, to the bottom of sawing line pattern SL. In some examples, the dividing may involve an initial backside grinding step, which may provide discrete first front substrates 101 that are separated from one another, but still connected by first molding film 140. In this case, the dividing may also involve a second step of separating chips 100 by cutting first molding film 140. The plurality of chips may then be isolated from each other in the second direction D2.

As shown in FIG. 11B, the plurality of chips may include chip pads 108. In the example illustrated in FIG. 11B, chip pads 108 may be added at the bottom of the divided chips, for example so as to make electrical contact with the bottom layer of the chip stack, as in the example of FIG. 12. However, the present invention is not limited thereto. For example, chip pads 108 may be added at the top of the divided chips so as to make electrical contact with the bottom layer of the chip stack after the divided chips are turned upside down, as in the example of FIG. 13.

In some examples, the cutting may be performed in two horizontal directions (e.g., along the second direction D2 and along a horizontal direction perpendicular to D2) to provide a grid shape of cuts. In this case, the resulting plurality of chips may be isolated in both the second direction D2 and the horizontal direction perpendicular to D2. Because the first blocking films 120 may prevent the first pre-spacer film 130P from covering the region of the sawing line pattern SL, during cutting, it may not be necessary to cut through the material of first pre-spacer film 130P. Accordingly, cutting to divide the first front substrate 101 in the second direction D2 may be facilitated and cutting accuracy may be improved. In some cases (e.g., in some embodiments according to either FIG. 11A or FIG. 11B), a shape of the first spacer film 130 covering the plurality of chips may change during grinding the plurality of chips with different heights. Since the first pre-spacer film 130P (of FIG. 10) covering a side surface of a chip with a relatively greater height (e.g., the second chip 100B of FIG. 10) is ground more, as an upper curved portion is ground, the first spacer film 130 may have a flat side surface after grinding, as in the example of FIG. 3 above. Since the first pre-spacer film 130P (of FIG. 10) covering a side surface of a chip with a relatively smaller height (e.g., the first chip 100A of FIG. 10) is ground less, the first spacer film 130 may still have a curved shape after grinding.

In some cases (e.g., in some embodiments according to either FIG. 11A or FIG. 11B), when the plurality of chips with different heights are ground, the chip with the relatively greater height (e.g., the second chip 100B of FIG. 10) may be subjected to damage. However, since the disclosed first spacer film 130 covers the side surfaces of the plurality of chips in a grinding direction, as an example, in a direction crossing the first direction D1, the first spacer film 130 may absorb some of the impact such as vibration generated while the plurality of chips with the different heights are ground. Therefore, the disclosed first spacer film 130 may prevent damage to a chip when the plurality of chips are ground.

FIGS. 12 and 13 show additional steps that may be performed with respect to the undivided chips of FIG. 11A. For example, the undivided chips of FIG. 11A may be placed at the bottom of the chip stack of FIGS. 12 and 13, whereas the higher layers of chips (e.g., the divided chips stacked on top of the bottom layer) may be formed according to the process of FIG. 11B.

Referring to FIG. 12, the plurality of chips cut and isolated in the second direction D2 and ground may be laminated onto the first front substrate 101. As an example, the second chip 200 in which the second spacer film 230, the second blocking film 220, and the second molding film 240 are formed may be placed on the first chip 100. The second front substrate 201 of the second chip 200 may be laminated onto the first chip 100 so as to be bonded to the first rear substrate 102 of the first chip 100, as in the examples of FIGS. 1, 3 and 4.

According to example embodiments, the first molding film 140 and the second molding film 240 may be in contact with each other when the second chip 200 is bonded onto the first chip 100. The first molding film 140 and the second molding film 240 including a resinous material may have higher adhesive strength than that of an oxide film. In some examples, the resinous material of first molding film 140 and second molding film 240 may also have higher adhesive strength than the resinous material of first pre-spacer film 130P. Accordingly, since the first molding film 140 and the second molding film 240 with the high adhesive strength are in contact with each other during bonding of the first chip 100 and the second chip 200, adhesive strength between the first chip 100 and the second chip 200 may be enhanced. For example, the bonding between the first chip 100 and the second chip 200 may be strengthened using the first molding film 140 and the second molding film 240.

According to example embodiments, the second chips 200 in which the second spacer film 230, the second blocking film 220, and the second molding film 240 are formed may be identical to and formed in the same manner as the plurality of chips 100 formed from the first front substrate 101 is cut to be divided along the second direction D2 and the first front substrate 101 and the first rear substrate 102 are ground in FIG. 11B.

According to example embodiments, the plurality of second chips 200 may be laminated onto the first front substrate 101 in a state in which the first front substrate 101 disposed at a lowermost portion is not cut to be divided along the second direction D2 and in which a lower surface of the first front substrate 101 is not ground. However, example embodiments of the present disclosure are not limited thereto.

Subsequently, referring to FIG. 1, the third chip 300 and the fourth chip 400 may be bonded to be laminated onto the second chip 200. Similarly to the second chip 200, the third chip 300 and the fourth chip 400 may be sequentially bonded onto the second chip 200 using the third molding film 340 and the fourth molding film 440, which may also improve adhesion of these bonds.

FIG. 13 is an example embodiment illustrating an intermediate process for explaining a method of fabricating a semiconductor package according to other example embodiments illustrated in FIG. 2. However, for the convenience of explanation, details different from those described with reference to FIGS. 5 through 12 will be described. For reference, FIG. 13 illustrates a process following FIG. 11B.

Referring to FIGS. 11A through 13, the second rear substrate 202 of the second chip 200 may be laminated to be bonded to the first rear substrate 102 of the first chip 100. As an example, a plurality of chips cut, isolated, and ground may be turned upside down in the first direction D1 and laminated onto the first front substrate 101. The first spacer film 130 and the second spacer film 230 may be in contact with each other. When compared to a case (e.g., in FIG. 12) in which the second front substrate 201 of the second chip 200 is bonded to the first rear substrate 102 of the first chip 100, when the second rear substrate 202 of the second chip 200 is bonded to the first rear substrate 102 of the first chip 100, a surface area in which the first molding film 140 and the second molding film 240 are in contact with each other may increase. Therefore, adhesion and bonding between the first chip 100 and the second chip 200 may be strengthened.

Then, referring to FIG. 2, the third chip 300 and the fourth chip 400 may be laminated onto the second chip 200. The third front substrate 301 of the third chip 300 may be laminated to be bonded to the second front substrate 201 of the second chip 200. The fourth rear substrate 402 of the fourth chip 400 may be laminated to be bonded to the third rear substrate 302 of the third chip 300.

According to example embodiments, it is possible to provide a semiconductor package with improved reliability.

While the present disclosure has been described in detail in connection with example embodiments, however, the scope of the present disclosure is not limited thereto and it is to be understood by those skilled in the art that the present disclosure is intended to cover various modifications and equivalent arrangements within the spirit and scope of the appended claims. In addition, the above-described example embodiments may be implemented with some elements thereof removed, and each example embodiment may be combined and implemented.

1. A semiconductor package comprising:
a first chip;
a second chip disposed on the first chip along a first direction;
a first spacer film disposed below the second chip and covering at least a portion of a side surface of the first chip; and
a first molding film disposed below the second chip and disposed to cover a side surface of the first spacer film,
wherein the first spacer film and the first molding film comprise materials that are different from each other, and
the side surface of the first spacer film is convex.

2. The semiconductor package of claim 1, wherein a width of the first spacer film along a second direction crossing the first direction decreases as the first spacer film becomes closer to the second chip.

3. The semiconductor package of claim 1,
wherein the first chip comprises a first front substrate including a first device layer and a first rear substrate disposed on the first front substrate and facing the second chip, and
wherein the first spacer film is disposed to cover a side surface of the first rear substrate on the first front substrate.

4. The semiconductor package of claim 3, further comprising a first blocking film which is hydrophobic and disposed at the first front substrate.

5. The semiconductor package of claim 4, wherein the first spacer film is not in contact with the first blocking film.

6. The semiconductor package of claim 4, wherein the first spacer film does not overlap with the first blocking film in the first direction.

7. The semiconductor package of claim 4, wherein the first molding film is disposed to cover the first blocking film.

8. The semiconductor package of claim 3, wherein the first molding film is disposed to cover a side surface of the first front substrate.

9. The semiconductor package of claim 1, wherein an upper surface of the first spacer film and an upper surface of the first molding film are disposed on the same plane.

10. (canceled)

11. A semiconductor package comprising:
a first chip including a first front substrate and a first rear substrate disposed on the first front substrate along a first direction and penetrated by a first through via;
a second chip disposed on the first chip along the first direction;
a first blocking film disposed on an upper surface of the first front substrate;
a first spacer film covering at least a portion of a side surface of the first chip below the second chip and not in contact with the first blocking film;
a first molding film disposed to cover a side surface of the first spacer film below the second chip;
a second spacer film disposed on the first chip and covering at least a portion of a side surface of the second chip; and
a second molding film disposed on the first chip and disposed to cover a side surface of the second spacer film,
wherein the first spacer film and the second spacer film include a first resin and the first molding film and the second molding film include a second resin that is different from the first resin.

12. The semiconductor package of claim 11, wherein the first spacer film and the second spacer film are in contact with each other.

13. The semiconductor package of claim 12, wherein, in a second direction crossing the first direction, a width of an upper surface of the first spacer film in contact with the second spacer film and a width of a lower surface of the second spacer film in contact with the first spacer film differ from each other.

14. The semiconductor package of claim 12, wherein a width of the first spacer film along a second direction crossing the first direction decreases as the first spacer film becomes closer to the second chip.

15. The semiconductor package of claim 12, wherein a width of the second spacer film along a second direction crossing with the first direction decreases as the second spacer film becomes closer to the first chip.

16. The semiconductor package of claim 11, wherein the first molding film and the second molding film are in contact with each other.

17. The semiconductor package of claim 11, wherein a lower surface of the first through via is disposed below a lower surface of the first blocking film.

18. The semiconductor package of claim 11, wherein a minimum width of the first spacer film and a minimum width of the second spacer film along with respect to a second direction crossing the first direction differ from each other.

19. The semiconductor package of claim 11, wherein, in a second direction crossing the first direction, a width of a lower surface of the second spacer film facing the first spacer film and a width of an upper surface of the first spacer film facing the second spacer film differ from each other.

20. The semiconductor package of claim 11, wherein the first blocking film is hydrophobic.

21. A semiconductor package comprising:
a first chip including a first front substrate and a first rear substrate disposed on the first front substrate along a first direction and penetrated by a first through via;
a second chip including a second rear substrate disposed on the first rear substrate along the first direction and penetrated by a second through via and a second front substrate disposed on the second rear substrate;
a first blocking film disposed on an upper surface of the first front substrate;
a first spacer film disposed to cover a side surface of the first rear substrate on the first front substrate and not in contact with the first blocking film;
a first molding film disposed to cover a side surface of the first spacer film below the second chip;
a second blocking film disposed on a lower surface of the second front substrate;
a second spacer film disposed to cover a side surface of the second rear substrate below the second front substrate, not in contact with the second blocking film, and in contact with the first spacer film; and
a second molding film disposed to cover a side surface of the second spacer film on the first chip and in contact with the first molding film.
